(19) United States
(12) Patent Application Publication
(10) Pub. No.: US 2007/0091962 A1
(43) Pub. Date: Apr. 26, 2007

(54) Substrate for vertical cavity surface emitting laser ( VCSEL) and method for manufacturing VCSEL device

(75) Inventors: Akemi Murakami, Kanagawa (JP); Hiromi Otoma, Kanagawa (JP); Ryoji Ishii, Kanagawa (JP)

Correspondence Address: FILDES & OUTLAND, P.C., 20916 MACK AVENUE, SUITE 2, GROSSE POINTE WOODS, MI, 48236, US

(73) Assignee: Fuji Xerox Co., Ltd.

(21) Appl. No.: 11/491,794

(22) Filed: Jul. 24, 2006

(30) Foreign Application Priority Data
Oct. 25, 2005 (JP) 2005-309493

(51) Int. Cl. H01S 5/00

(52) U.S. Cl. 372/50.124

(57) ABSTRACT

The present invention provides a substrate for a VCSEL that improves reliability and yield. A substrate for VCSEL includes multiple element regions separated by an element dividing region that is scribed or diced. In each element region, a light emitter that emits laser light in a direction perpendicular to the substrate, and an electrode pad electrically coupled to the light emitter are formed. In the element dividing region, electrode pads for inspection each electrically coupled to the light emitter of each element region is formed.

### BACKGROUND

1. Technical Field

The present invention relates to a method for manufacturing Vertical Cavity Surface Emitting Laser (hereinafter referred to as VCSEL).

2. Related Art

VCSELs have been increasingly used as parallel light sources that can be highly integrated two dimensionally for optical interconnection, optical memory, optical transmission, optical data processing, laser beam printers, or copying machines, for example.

A VCSEL includes a resonator formed on a substrate of a semiconductor such as GaAs, by stacking a lower Distributed Bragg Reflector (DBR) and an upper DBR to interpose an active layer. Light generated at the active layer is amplified at the resonator, and the VCSEL emits laser light in a direction substantially perpendicular to the substrate. Multiple VCSELs having such a perpendicular resonator configuration can be formed in two-dimensional arrays on a substrate. On a substrate, multiple element regions are formed each of which includes a light emitter that emits laser light, and the multiple element regions are separated by an element dividing region for scribing or dicing.

The multiple element regions are cut into chips by dicing the element dividing region. Generally, a chip is bare-mounted on a wiring board, or packaged in a can or resin and the package is mounted on a wiring board.

In general, properties evaluation of the light emitters is conducted while they are on a wafer before the chips or element regions are cut out from the wafer. The properties evaluation is performed by bringing a probe tip into contact with the electrode pad in the element region, applying current to the light emitter so that the light emitter actually emits light, and measuring output temperature properties, divergence angle (FFP: Far Field Pattern), or the like. The properties evaluation is generally conducted for each element region on a wafer sequentially one by one.

Each time the properties evaluation of the light emitter on a wafer is conducted, the probe tip is brought into contact with the electrode pad, and thus a probe mark is created. If there are many items to be evaluated, such as temperature properties and FFP, probe marks maybe created many times. These marks are visually unsightly, and what is worse, may be judged as failure at visual inspection. In addition, damages on the electrode pad surface due to multiple probe marks may cause difficulties in wire bonding in a subsequent mounting process, or cause contact failure.

To avoid these issues, there are a method to make an electrode pad having a larger pad diameter and perform wire bonding to another position than the probe marks, and a method to form other electrode pad for inspection. However, there has been a problem in that increase of the area of the electrode pad may increase capacity and inhibit high-speed response of the laser element.

### SUMMARY

An aspect of the present invention provides a substrate for VCSEL according to an aspect of the invention includes multiple element regions separated by an element dividing region that is scribed or diced. In each element region, alight emitter that emits laser light in a direction perpendicular to the substrate and a first electrode pad electrically coupled to the light emitter are formed. In the element dividing region, multiple second electrode pads each electrically coupled to the light emitter of each element region are formed.

### BRIEF DESCRIPTION OF THE DRAWINGS

Embodiments of the present invention will be described in detail based on the following figures, wherein:

FIG. 1 is a plan view of a substrate for VCSEL according to an exemplary embodiment of the present invention;

FIG. 2 is an enlarged view of an element region and an element dividing region formed on the substrate of FIG. 1;

FIG. 3 is a cross sectional view of FIG. 2 taken along line A-A;

FIG. 4 is an enlarged view of an element dividing region (portion B) of FIG. 3;

FIG. 5 shows a bonding example of an electrode pad in an element region;

FIGS. 6A and 6B are cross sectional views of modifications of an undercoating layer of an electrode pad for inspection;

FIG. 7 shows an example of another arrangement of electrode pads for inspection;

FIG. 8 shows an example of an element region of a substrate for VCSEL according to an exemplary embodiment;

FIGS. 9A to 9C are cross sectional views of a substrate for VCSEL to schematically show a manufacturing process according to an exemplary embodiment;

FIGS. 10A to 10C are cross sectional views of a substrate for VCSEL to schematically show a manufacturing process according to an exemplary embodiment;

FIGS. 11A and 11B are cross sectional schematic views of substrate for VCSEL to schematically show a manufacturing process according to an exemplary embodiment;

FIG. 12 is a cross sectional view to show a structure of a can package;

### DETAILED DESCRIPTION

A VCSEL of the present invention will be now described in detail, referring to the accompanying drawings.

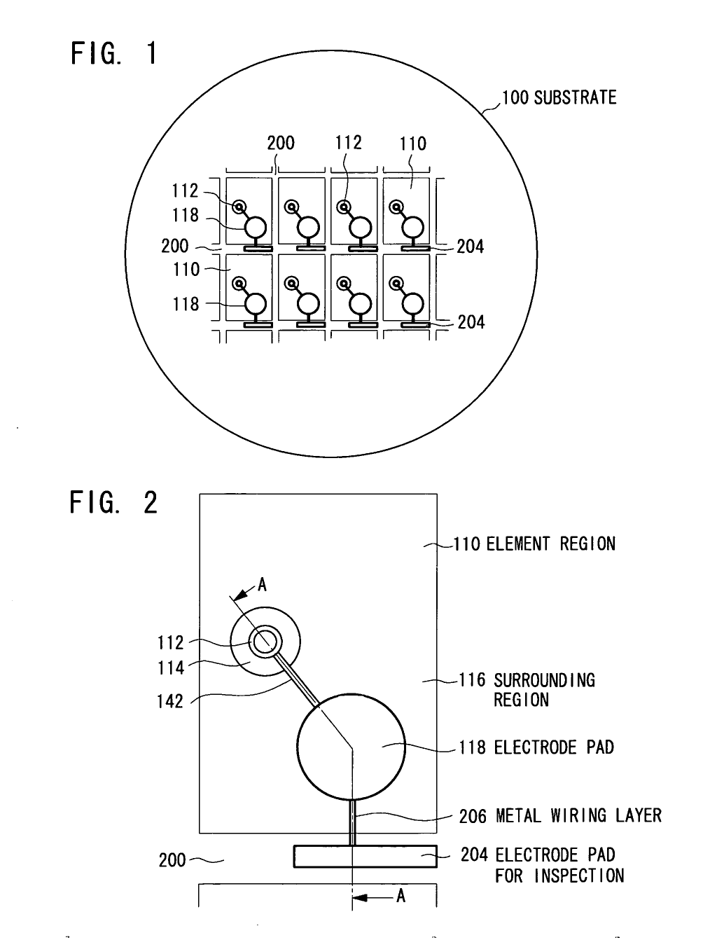

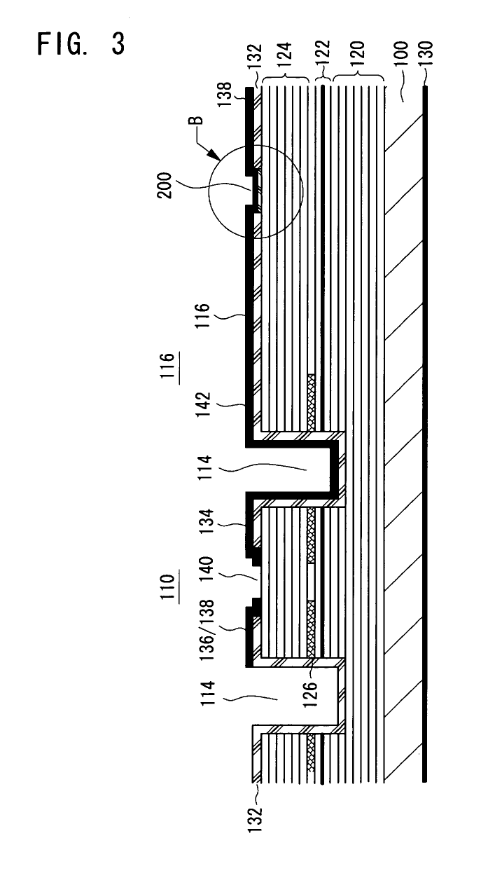

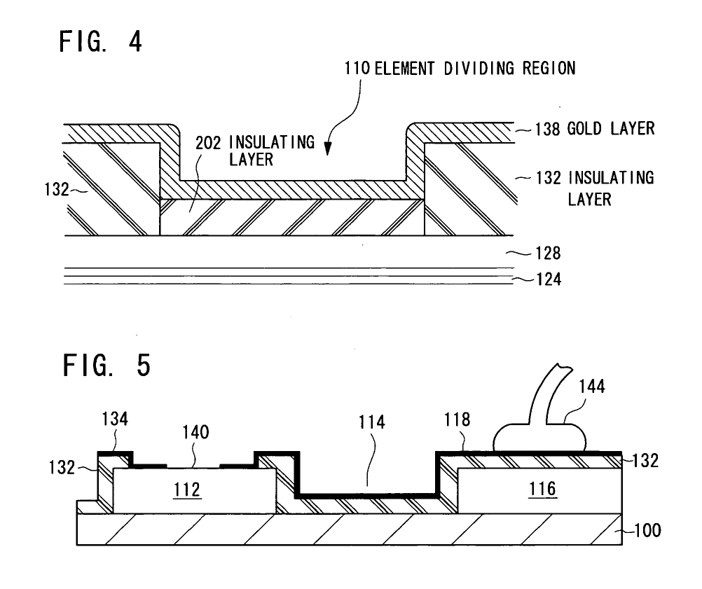

FIG. 1 shows a plan view of a substrate on which light emitters (laser elements) according to an exemplary embodiment are formed. FIG. 2 is an enlarged view of an element region formed on the substrate. FIG. 3 is a cross sectional view of FIG. 2 taken along line A-A. FIG. 4 is an enlarged view of portion B of FIG. 3. On a substrate shown in FIG. 1, multiple light emitters are formed. Properties evaluation of each of the light emitters is conducted on the substrate, and then judged as pass or fail. After that, the substrate is cut into multiple chips by a dicer, and mounting of each of the chips is performed.

As shown in FIG. 1, on a substrate 100, multiple element regions 110 and an element dividing region 200 for separating or partitioning the multiple element regions 110 are formed. The element regions 110, each having a rectangular shape, are arranged in arrays on the substrate. The element dividing region 200, having a width of about 50 um, extends vertically and horizontally in a lattice pattern.

In each element region 110, a light emitter 112 that emits laser light and a surrounding region 116 isolated by a trench or groove 114 from the light emitter 112 are formed. The groove 114 formed around the light emitter 112 has an annular shape, and thus the light emitter 112 is a cylindrical mesa or post structure. In the surrounding region 116, an electrode pad 118 is formed, and the electrode pad 118 is, as described later, coupled to a p-side electrode layer of the light emitter 112.

The light emitter 112 is formed as follows as shown in FIG. 3. Sequentially stacked on an n-type GaAs substrate 100 are: an n-type lower DBR 120 in which multiple periods of Al_{0.9}Ga_{0.1}As and Al_{0.3}Ga_{0.7}As are stacked; an active region 122 that includes an undoped lower spacer layer, an undoped quantum well active layer, and an undoped upper spacer layer; and a p-type upper DBR 124 in which multiple periods of Al_{0.9}Ga_{0.1}As and Al_{0.3}Ga_{0.7}As are stacked. At the bottommost of the upper DBR 124, a p-type AlAs layer 126 is formed. At the topmost of the upper DBR 124, a contact layer 128 made of p-type GaAs is formed. On the back surface of the substrate 100, an n-side electrode 130 is formed.

The light emitter 112 is formed by etching semiconductor layers from the contact layer 128, until part of the lower DBR 120 is exposed. The AlAs layer 126 contained in the mesa of the light emitter 112 has an oxidized region 126a part of which is oxidized from side surface of the mesa, and a round aperture (conductive region) 126b surrounded by the oxidized region 126a. The AlAs layer 126 works as a current-confined layer that confines light and carriers in the aperture 126b surrounded by the oxidized region 126a.

The element region 110 that includes the light emitter 112, groove 114, and surrounding region 116 is covered with a patterned insulating layer 132. The insulating layer 132 is formed of, for example, SiON or SiO₂. In the insulating layer 132, a round contact opening is formed to expose the contact layer 128 at the top of the light emitter 112. In addition, the insulating layer 132 is patterned corresponding to the size of the element region 110 so that the element dividing region 200 is exposed.

On the insulating layer 132, a patterned p-side electrode layer 134 is formed. The p-side electrode layer 134 is formed by stacking a titanium (Ti) layer 136 and a gold (Au) layer 138, and electrically coupled to the contact layer 128 at the top of the light emitter 112 through the contact opening of the insulating layer 132. In addition, at the top of the light emitter 112, a round emitting window 140 is formed in the p-side electrode layer 134, and laser light is emitted from the emitting window 140.

The surrounding region 116 includes semiconductor layers having the same structure as the light emitter 112 does. On the topmost of the semiconductor layers, namely, the contact layer 128, the insulating layer 132 is formed. At a predetermined position on the insulating layer 132, the electrode pad 118 is formed. The electrode pad 118 is coupled to the p-side electrode layer 134 by the metal wiring layer 142. Preferably, the electrode pad 118 and the metal wiring layer 142 are simultaneously formed by patterning the titanium layer 136 and gold layer 138 deposited on the insulating layer 132. The titanium layer 136 interposed between the gold layer 138 and the insulating layer 132 improves adhesion of the gold layer 138, namely, the electrode pad 118, the metal wiring layer 142, to the insulating layer 132.

The element dividing region 200 has a thin insulating layer 202 that covers the GaAs contact layer 128 exposed by the insulating layer 132. The insulating layer 202 is formed of, for example, SiON or SiO₂. On the insulating layer 202, an electrode pad 204 for inspection is formed. The electrode pad 204 for inspection is coupled to the electrode pad 118 by a strip of metal wiring layer 206. Preferably, adhesion of the electrode pad 204 for inspection to the insulating layer 202 is not necessarily so strong, so that the pad is easily removed during dicing. Thus, the electrode pad 204 for inspection may be made of gold or gold alloy. Similarly, the metal wiring layer 206 may also be formed of gold or gold alloy. The electrode pad 204 for inspection and the metal wiring layer 206 may be formed simultaneously with the patterning of the gold layer of the electrode pad 118 and the metal wiring layer 142, or may be formed by patterning in separate processes. For example, when the electrode pad 118 and the metal wiring layer 142 are formed, initially, the titanium layer 136 is deposited. At this time, the region where the metal wiring layer 206 is formed and the element dividing region 200 are masked so that titanium layer 136 is not deposited thereon. After the mask is removed, the gold layer 138 is deposited on the entire substrate. Then, the gold layer 138 is patterned to form the p-side electrode layer 134, electrode pad 118, metal wiring layer 142, metal wiring layer 206, and electrode pad 204 for inspection. FIG. 4 is an enlarged view of the element dividing region 200 shown in FIG. 3. On the insulating layer 202, the gold layer 138 to form the electrode pad 204 for inspection is formed.

The electrode pad 118 is coupled to the insulating layer 132 through the titanium layer 136, while the electrode pad 204 for inspection is coupled to the insulating layer 202 through the gold layer 138. Thus, the electrode pad 204 for inspection has a relatively weaker adhesion compared with that of the electrode pad 118. In a case the metal wiring layer 206 is formed of gold layer, its adhesion also becomes weaker.

For one element region 110, one electrode pad 204 for inspection is formed. In other words, the number of electrode pads 204 for inspection that are formed corresponds to the number of the element regions 110 formed on a substrate. It is preferable that each of the electrode pads 204 for inspection is linearly arranged on the element dividing region 200, and all of the electrode pads 204 for inspection are removed during subsequent dicing.

Before the element regions 110 are diced from the substrate 100, properties evaluation of the light emitters 112 is conducted while they are on the wafer. Properties evaluation, which inspects temperature properties and divergence angle (FFP), for example, is conducted in a condition where the light emitter 112 is actually operated and laser light is emitted from the light emitter 112. The inspection for temperature properties is performed at multiple temperatures, for example, an ambient temperature (25 degrees Celsius), a low temperature (−20 degrees Celsius), and a high temperature (85 degrees Celsius).

When properties evaluation is conducted, the n-side electrode 130 of the substrate is grounded to a reference voltage, and a probe tip is brought into contact with a selected electrode pad 204 for inspection. When current is applied from the probe tip, driving current is provided from the electrode pad 204 for inspection, through the metal wiring layer 206, electrode pad 118, and wiring layer 142 to the p-side electrode layer 134. This enables the light emitted at the active region 122 to be amplified at the resonators of the upper and lower DBRs 120 and 126, and emitted from the emitting window 140.

When the properties evaluation of a light emitter 112 of one element region 110 is completed, the probe tip is released from the electrode pad 204 for inspection, and to conduct properties evaluation of next light emitter 112 of the element region 110, the probe tip is pressure-contacted onto a corresponding pad 204 for inspection. After the whole properties evaluation for all light emitters 112 is completed, marking is provided to each element region 110 so that judged results of pass or fail can be identified.

Then, the substrate 100 is adhered to an adhesive film or the like, and the substrate is cut along the element dividing region 200 by using a dicer. At this time, the entire or part of the electrode pads 204 for inspection arranged along the element dividing region 200 are removed by the dicer. The electrode pads 204 for inspection are easily delaminated or removed during the cutting by the dicer because their adhesion to the insulating layer 202 is weak as described above.

In a subsequent mounting process, each of the chips cut into the element regions is encapsulated in a package, such as a can or resin. Because the electrode pad 118 of the element region is not contacted by the probe tip during the properties evaluation, its surface keeps a flat condition. Therefore, visual failure of the electrode pad 118 is eliminated, and yield is improved. In addition, the flatness of the surface of the electrode pad 118, which is then coupled to a bonding wire 144 as shown in FIG. 5, results in better bonding and avoids bonding failure due to probe marks.

Furthermore, the element region 110 contains only the electrode pad 118 and does not contain the electrode pad 204 for inspection, and thus response is not impaired due to the capacity increase of the light emitter 112.

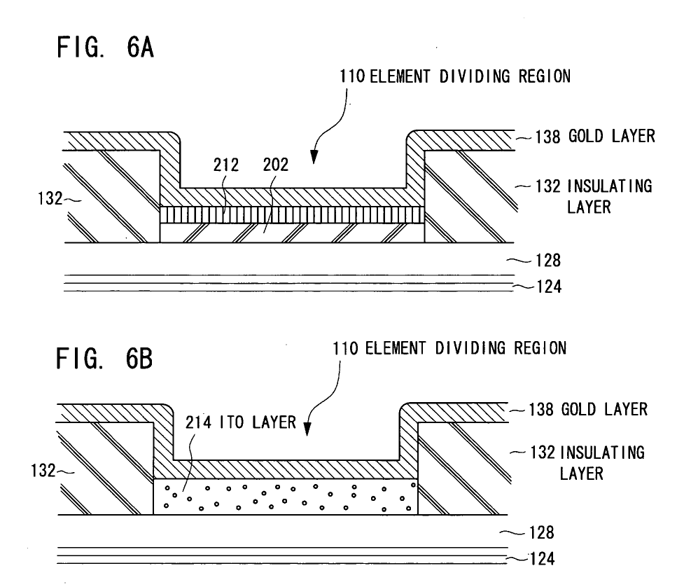

Modification examples of the pad for inspection formed on the element dividing region will be now described. In the example above, the electrode pads 204 for inspection made of the gold layer 138 is formed on the insulating layer 202 formed in the element dividing region 200. However, as shown in FIG. 6A, a polyimide layer 212 may be formed on the insulating layer 202, and on the polyimide layer 212, an electrode pads 204 for inspection made of gold or gold alloy may be formed. Alternatively, the polyimide layer 212 may be formed directly on the contact layer 128. By using the polyimide layer as undercoating, the electrode pads 204 for inspection may be removed more easily.

In addition, the undercoating of the electrode pad 204 for inspection may be formed of a layer that can be easily delaminated using chemical solution. For example, an ITO (Indium Tin Oxide) layer 214 is formed on the insulating layer 202, and on the ITO layer 214, an electrode pad 204 for inspection made of gold or gold alloy may be formed. Alternatively, as shown in FIG. 6B, the ITO layer 214 may be formed directly on the GaAs contact layer 128. The ITO layer 214 is readily dissolved in, for example, diluted hydrochloric acid, and thus the electrode pad 204 for inspection can be easily delaminated together with the ITO layer 214. In this case, the element region is covered with a resist when the ITO layer is removed.

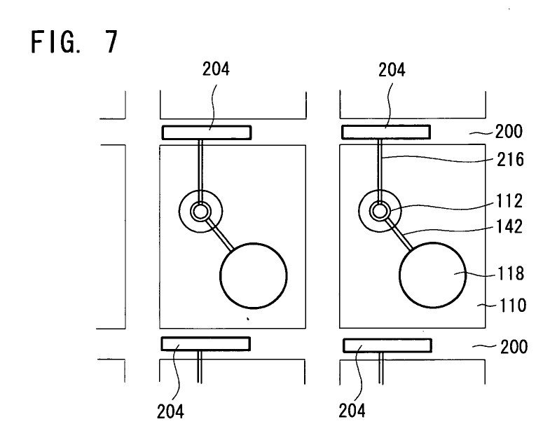

Next, other arrangements of the electrode pad for inspection are described. In the example above, an example where the electrode pad for inspection is coupled to the electrode pad 118 through the metal wiring layer 206. However, as shown in FIG.7, the electrode pad 204 for inspection may be placed on the side opposing to electrode pad 118, and coupled to the p-side electrode layer 134 by the metal wiring layers 216.

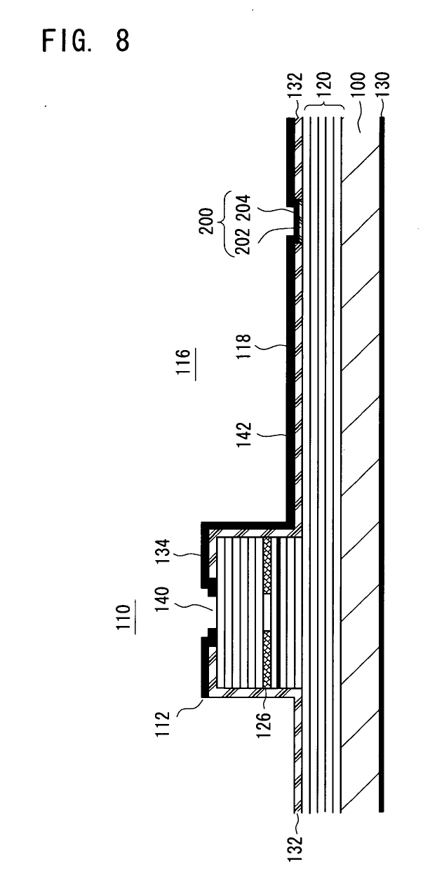

In the example above, the groove 114 is formed around the light emitter 112, and the light emitter 112 and the surrounding region 116 contain the same semiconductor layers. However, for example, as shown in FIG.8, amesa-like light emitter 112 maybe remained on the element region 110, and the electrode pad 118 may be formed at the bottom of the mesa. The electrode pad 118 is formed at the bottom of the mesa, i.e. on the insulating layer 132 that covers the lower DBR120. In the element dividing region 200, the insulating layer 202, electrode pads 204 for inspection are formed on an exposed lower DBR.

Furthermore, in the example above, shown in the element region 110 is so-called single spot in which a single light emitter 112 is formed. However, it maybe so-called multi spot, i.e., multiple light emitters 112 are formed in the element region 110. The multiple light emitters may be arranged linearly, or may be arranged in two dimensions. The electrode pads for inspection are formed so that each of them corresponds to each element region, and one electrode pad for inspection is electrically coupled to the p-side electrode layer of each of the multiple light emitters in one element region.

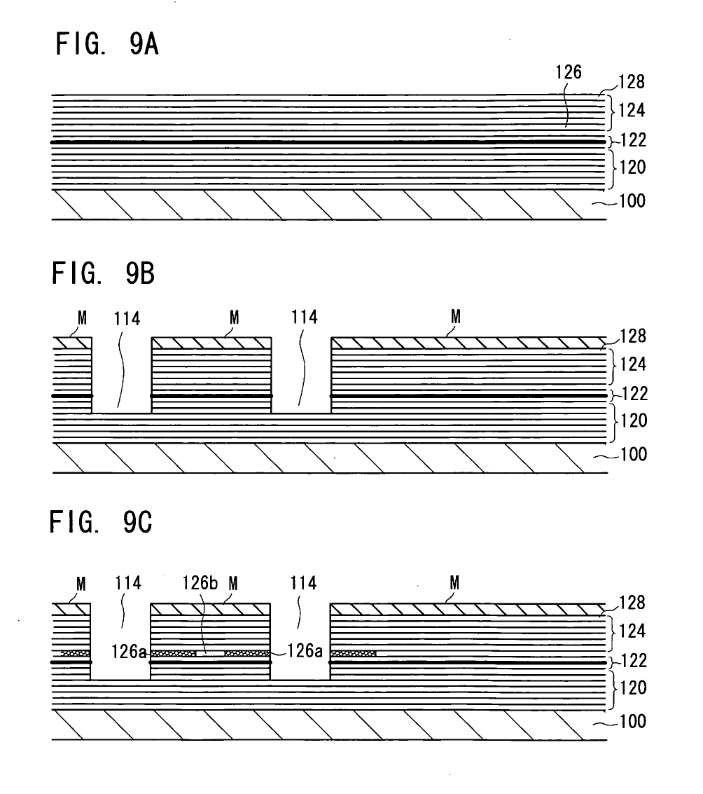

Now, a method of manufacturing a VCSEL according to an aspect of the present invention is described referring to FIGS. 9A to 9C. As shown in FIG. 9A, on an n-type GaAs substrate 100, an n-type GaAs buffer layer having a carrier concentration of 1×10¹⁸ cm⁻³ and a film thickness of about 0.2 μm is deposited by Metal Organic Chemical Vapor Deposition (MOCVD) . Formed on the n-type GaAs buffer layer is a lower n-type DBR 120 in which 40.5 periods of Al_{0.9}Ga_{0.1}As and Al_{0.3}Ga_{0.7}As, each layer having a thickness of λ/4nᵣ (wherein λ is lasing wavelength, nᵣ is the medium refractive index), are alternately stacked. The carrier concentration of the lower n-type DBR 120 is 1×10¹⁸ cm^{31 3}. Formed on the lower n-type DBR 120 is an active layer region 122 made of an undoped lower Al_{0.5}Ga_{0.5}As spacer layer, an undoped quantum well active layer, and an undoped upper Al_{0.5}Ga_{0.5}As spacer layer.

Formed on the active region 122 is an upper p-type DBR 124 in which 30 periods of Al_{0.9}Ga_{0.1}As and Al_{0.3}Ga_{0.7}As are alternately stacked so that each film thickness has ¼ of the wavelength in the medium. The carrier concentration is 1×10¹⁸ cm⁻³. At the bottommost of the upper DBR 124, a low-resistance p-type AlAs layer 126 is included, and at the topmost of the upper DBR 124, a p-type GaAs contact layer 128 having a carrier concentration of 1×10¹⁹ cm^{31 3} and a film thickness of about 10 nm is stacked.

Then, as shown in FIG. 9B, by using a predetermined mask pattern M, etching is performed by Reactive Ion Etching (RIE) until part of the lower n-type DBR 120 is exposed to form a trench or groove 114. By this etching, a light emitter 112 having a cylindrical mesa structure isolated by the groove 114 and a surrounding region 116 are formed in the element region 110.

Next, the substrate is placed in an oxidation oven to perform oxidation process as shown in FIG. 9C. Part of the current-confined layer (AlAs layer) 126 in the mesa l2 isoxidized in the oxidation process. At this time, high-Al-composition AlGaAs and AlAs layers change into alminum oxide (AlxOy). AlAs has a far faster oxidation speed than AlGaAs does, and thus only AlAs is selectively oxidized from the side surface of the mesa toward the center part of the mesa, and finally an oxidized region 126a corresponding to the outline of the mesa is formed. The oxidized region 126a becomes a current-confined portion having a lower conductivity, and also works as a light-confined region. This is because the oxidized region 126a has almost half optical refractive index (˜1.6) compared with that of neighboring semiconductor layers, and thus light and carriers are confined in the aperture 126b.

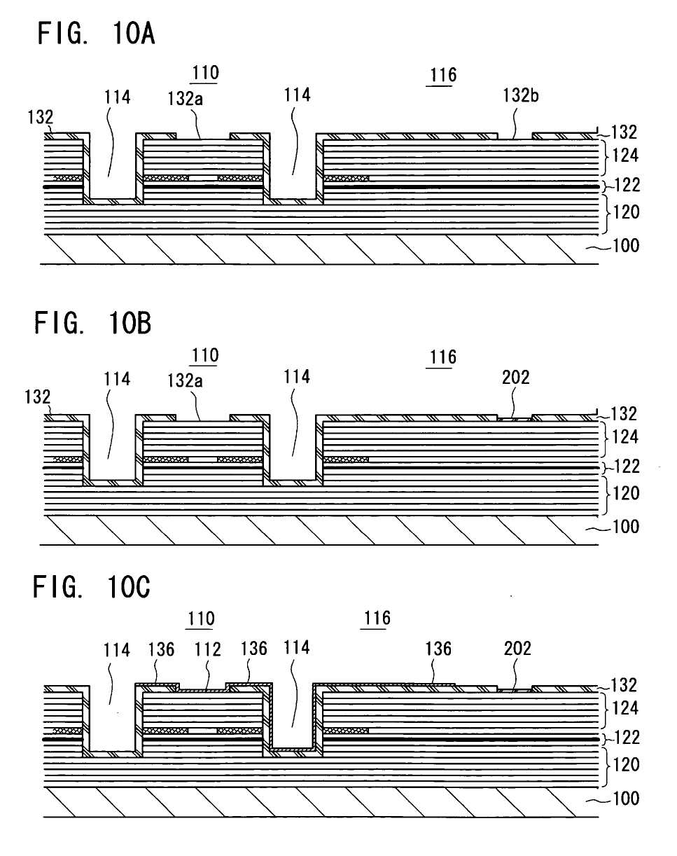

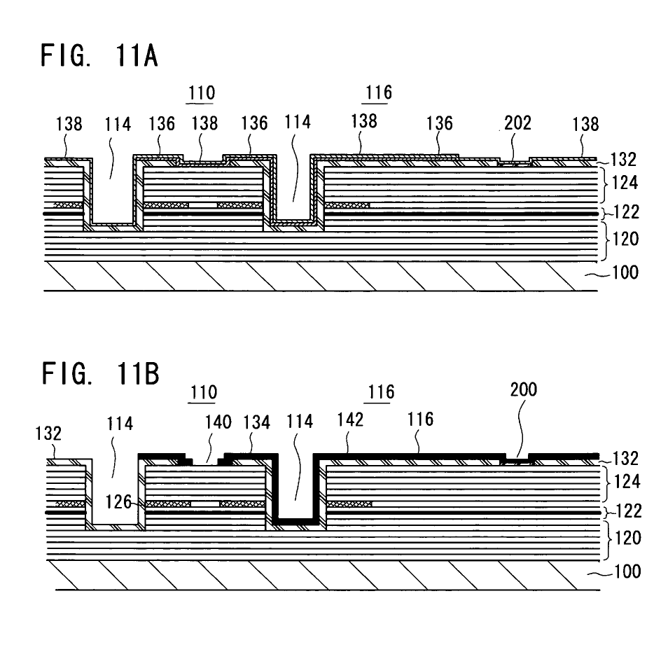

Then, an insulating layer such as SiN or SiON is formed over the entire substrate, and as shown in FIG. 10A, the insulating layer 132 is patterned. At the top of the light emitter 112, a round contact opening 132a to expose the contact layer128 is formed, and a lattice pattern opening 132b is formed to partition the element region 110. The lattice pattern opening 132b corresponds to the element dividing region 200.

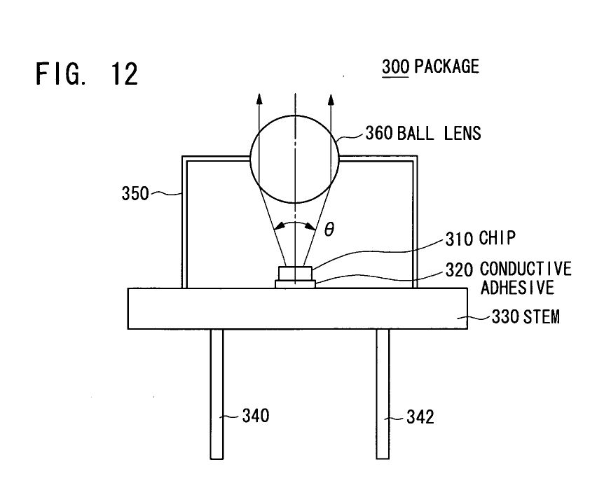

Next, by using a predetermined photolithography process, an insulating layer 202 is formed in the opening 132b as shown in FIG. 10B. After that, as shown in FIG. 10C, in the region where the light emitter 112 and electrode pad 118 are formed, a titanium layer 136 is deposited, and then, as shown in FIG. 11A, a gold layer 138 is deposited over the entire substrate. On the insulating layer 132 in the region of the element region 110 ranging from the light emitter 112 to the electrode pad 118, titanium/gold layers 136, 138 are formed. On other element region and the insulating layer 202 of element dividing region 200, the gold layer 138 is formed.

Then, as shown in FIG. 11B, the p-side electrode layer 134, metal wiring layer 142, electrode pad 118, electrode pad 204 for inspection, and metal wiring layer 206 are patterned. Then, as an n-side electrode 130, Au/Ge is formed on the back surface of the substrate.

Then, properties evaluation of each of the light emitters 112 is performed while they are on the substrate, and then dicing of the substrate is performed along the element dividing region 200. Diced chips are each encapsulated in a can package.

FIG. 12 is a cross sectional view to show a structure of a can package for an optical module. As shown in FIG. 12, in a package 300, a diced chip 310 is fixed on a disc-shaped metal stem 330 through a conductive adhesive 320. Conductive leads 340, 342 are inserted into a through hole (not shown) formed in the stem 330. One lead 340 is electrically coupled to an n-side electrode formed on the back surface of the chip 310, and the other lead 342 is electrically coupled to a p-side electrode formed on the surface of the chip 310, for example, via a bonding wire.

On the stem 330, a rectangular hollow cap 350 is fixed to contain the chip 310, and a ball lens 360 is fixed in a center opening of the cap 350. The optical axis of the ball lens 360 is positioned to match an approximate center of the chip 310. When a forward voltage is applied between the leads 340 and 342, laser light is emitted from each mesa of the chip 310. The distance between the chip 310 and the ball lens 360 may be adjusted so that the ball lens 360 is contained within the radiation angle θ of the laser light from the chip 310. In addition, in the cap, a light sensing element may be contained to monitor the emitting status of the VCSEL.

While exemplary embodiments of the present invention have been described in detail, it is not intended to limit the invention to these specific exemplary embodiments according to an aspect of the invention. It should be understood that various modifications and changes may be made without departing from the inventive scope which is defined by the following claims.

A semiconductor laser device according to an aspect of the invention is widely applicable to light sources for printers, copying machines, or light sources for optical communication, optical network, for example.

What is claimed is:

1. A substrate for Vertical Cavity Surface Emitting Laser (VCSEL) comprising a plurality of element regions separated by an element dividing region that is scribed or diced; each of the element regions comprising a light emitter that emits laser light in a direction perpendicular to the substrate, and a first electrode pad electrically coupled to the light emitter; and the element dividing region comprising a plurality of second electrode pads each electrically coupled to the light emitter of each of the element regions.

2. The substrate for VCSEL according to claim 1, wherein the second electrode pads being arranged along the element dividing region.

3. The substrate for VCSEL according to claim 1, wherein the second electrode pads being linearly arranged along the element dividing region.

4. The substrate for VCSEL according to claim 1, wherein the second electrode pads being coupled to a first electrode pad in a corresponding element region through a metal layer.

5. The substrate for VCSEL according to claim 1, wherein the second electrode pads being coupled to a light emitter in a corresponding element region through a metal layer.

6. The substrate for VCSEL according to claim 1, wherein the second electrode pads being formed through an undercoating layer different from an undercoating layer of the first electrode pad.

7. The substrate for VCSEL according to claim 6, wherein the first electrode pad comprising a stack structure of titanium and gold on an insulating layer, and the second electrode pads comprising a gold layer on the insulating layer.

8. The substrate for VCSEL according to claim 6, wherein the second electrode pads comprising gold or gold alloy on a polyimide layer.

9. The substrate for VCSEL according to claim 6, wherein the undercoating layer of the second electrode pads comprising an ITO layer.

10. The substrate for VCSEL according to claim 9, wherein the ITO layer being removable by hydrochloric acid, and when the ITO layer being removed, the second electrode pads being simultaneously removed.

11. The substrate for VCSEL according to claim 1, wherein the light emitter of the element region comprising, on the substrate, a first reflective layer of a first conductive type stacked to interpose an active layer and a second reflective layer of a second conductive type, wherein the first electrode pad and a second electrode pad being electrically coupled to the second reflective layer.

12. The substrate for VCSEL according to claim 1, wherein a back surface electrode being formed on the back surface of the substrate, and the back surface electrode being electrically coupled to a first reflective layer.

13. The substrate for VCSEL according to claim 11, wherein the light emitter of the element region comprising a mesa or post structure, and the mesa or post structure comprising a current-confined layer formed by selective oxidation.

14. The substrate for VCSEL according to claim 1, wherein the light emitter of the element region being isolated by a groove from a surrounding region, and the light emitter and the surrounding region comprising same semiconductor layers.

15. The substrate for VCSEL according to claim 1, wherein laser light emission from a selected light emitter being capable by applying current to the second electrode pads.

16. The substrate for VCSEL according to claim 1, wherein one element region comprising a plurality of light emitters, and the plurality of light emitters of the one element region being electrically coupled to one second electrode pad.

17. The substrate for VCSEL according to claim 1, wherein the first electrode pad being a pad for wire bonding, and the second electrode pads being electrode pads for inspection.

18. A method for manufacturing a VCSEL device that emits laser light in a direction perpendicular to a substrate, the method comprising:
providing a substrate, the substrate comprising:
a plurality of element regions having a light emitter and a first electrode pad electrically coupled to the light emitter, and an element dividing region to separate the plurality of element regions; and the element dividing region comprising second electrode pads electrically coupled to a light emitter of a corresponding element region, and the plurality of second electrode pads being arranged along the element dividing region,
inspecting properties of the light emitter by applying current to the second electrode pads,
scribing or dicing along the element dividing region after the inspection is completed, and
mounting diced chips.

19. The method for manufacturing a VCSEL device according to claim 18, the inspection comprising bringing a probe tip into contact with a selected second electrode pad.

20. The method for manufacturing a VCSEL device according to claim 19, wherein the second electrode pads being brought into contact with the probe tip a plurality of times.

21. The method for manufacturing a VCSEL device according to claim 18, part of or the entirety of the second electrode pads formed in the element dividing region being removed by the scribing or dicing.

22. The method for manufacturing a VCSEL device according to claim 18, the mounting comprising bonding of the first electrode pad.

23. The method for manufacturing a VCSEL device according to claim 18, wherein the second electrode pads being formed through an ITO layer, and after the inspection is completed, the second electrode pads being simultaneously removed when the ITO layer being removed by hydrochloric acid.
